(19) United States
(12) Patent Application Publication
(10) Pub. No.: US 2012/0037905 A1
(43) Pub. Date: Feb. 16, 2012

(54) DISPLAY DEVICE AND ELECTRONIC EQUIPMENT

(75) Inventors: Atsuhito Murai, Osaka-shi (JP); Yoshiharu Kataoka, Osaka-shi (JP); Takuya Watanabe, Osaka-shi (JP); Hajime Imai, Osaka-shi (JP); Hideki Kitagawa, Osaka-shi (JP)

(73) Assignee: Sharp Kabushiki Kaisha, Osaka-shi, Osaka (JP)

(21) Appl. No.: 13/265,766

(22) PCT Filed: Nov. 20, 2009
(86) PCT No.: PCT/JP2009/006287

§ 371 Date: Oct. 21, 2011

(30) Foreign Application Priority Data
Apr. 22, 2009 (JP) 2009-104411

(51) Int. Cl. H01L 31/153

(52) U.S. Cl. 257/53; 257/E31.102

(57) ABSTRACT

A display device of the present invention includes a display panel (101) including a photodiode (17), which generates a current having a magnitude corresponding to an intensity of light incident on the photoelectric conversion element; and, a backlight (108) for irradiating light from behind the photodiode (17) to beyond a front surface of the display panel (101), wherein: the photodiode (17) includes an activating layer made of hydrogenated a-Si; the light source (108) has a peak wavelength within a range from 780 nm or more to 830 nm or less; and the display device further includes a light blocking member (15) for blocking light having a wavelength less than 780 nm, the light blocking member (15) being provided between a front surface of the display panel (101) and the photodiode (17) and over the photodiode (17). With this, the present invention can perform a stable sensing operation under various environments because the display device is configured to reduce the outside-light-caused noise to the optical sensor and the display device is therefore less susceptible to environment surrounding the display device (outside light intensity etc.).

A display device of the present invention includes a display panel (101) including a photodiode (17), which generates a current having a magnitude corresponding to an intensity of light incident on the photoelectric conversion element; and, a backlight (108) for irradiating light from behind the photodiode (17) to beyond a front surface of the display panel (101), wherein: the photodiode (17) includes an activating layer made of hydrogenated a-Si; the light source (108) has a peak wavelength within a range from 780 nm or more to 830 nm or less; and the display device further includes a light blocking member (15) for blocking light having a wavelength less than 780 nm, the light blocking member (15) being provided between a front surface of the display panel (101) and the photodiode (17) and over the photodiode (17). With this, the present invention can perform a stable sensing operation under various environments because the display device is configured to reduce the outside-light-caused noise to the optical sensor and the display device is therefore less susceptible to environment surrounding the display device (outside light intensity etc.).

### REFERENCE TO RELATED APPLICATIONS

This application is a national stage application under USC 371 of International Application No. PCT/JP2009/006287, filed Nov. 20, 2009, which claims the priority of Japanese Patent Application No. 2009-104411, filed Apr. 22, 2009, the contents of which prior applications are incorporated herein by reference.

### FIELD OF THE INVENTION

The present invention relates to a display device including an optical sensor.

### BACKGROUND OF THE INVENTION

A display device including a display panel in which an optical sensor is provided in each pixel has been conventionally proposed.

To realize a touch sensor by utilizing such optical sensors, the display device is generally provided with a light source for emitting light to enter the optical sensors. This display device is configured such that the light source in the display device irradiates, with the light, an operator's finger pulp in touch with the display panel and the optical sensors receive light reflected from the finger pulp (finger-pulp reflected-light).

However, in the case where the light source for the touch sensor in the display device is a visible light source, the visible light from this visible light source may affect luminance of the display panel of the display device, thereby causing a display quality deterioration.

In view of this, Patent Literatures 1 to 3 etc. have proposed display devices in which light sources for optical sensors are infrared light sources, which are light sources that do not affect the luminance of display panels.

### CITATION LIST

### Patent Literature

Patent Literature 1

Japanese Patent Application Publication, Tokukai, No. 2004-264846 A (Publication Date: Sep. 24, 2004)

Patent Literature 2

Japanese Patent Application Publication, Tokukai, No. 2008-003296 A (Publication Date: Jan. 10, 2008)

Patent Literature 3

Japanese Patent Application Publication, Tokukai, No.

### SUMMARY OF THE INVENTION

A photodiode (photoelectric conversion element) is generally used as the aforementioned optical sensor. Sensitivity of a photodiode is indicated by S (signal)/N (noise) ratio. In order to enhance accuracy of the touch sensor, the sensitivity of the photodiode needs to be increased. In order to increase the sensitivity of the photodiode, it is necessary to increase S and/or decrease N.

However, in the display devices disclosed in Patent Literature 1 to 3, there is a risk that an intensity of visible light components of outside light incident on the photodiode is unignorably high in comparison with an intensity of the finger-pulp reflected-light incident on the photodiode (light emitted from an infrared light source and reflected on a finger pulp) depending on an environment in which the display device is used. That is, there is a risk that a relationship “the outside light intensity (visible light region) the intensity of the finger-pulp reflected-light emitted from the infrared light source” may be established in the intensity of the light incident on the photodiode. In this case, the visible light components of the outside light are the noise(N) and reduce the sensitivity of the photodiode, whereby the accuracy of the touch sensor is consequently reduced.

In other words, according to Patent Literatures 1 to 3 or the like, an environment surrounding the display device (outside light intensity etc.) affects the display device and a stable sensing operation cannot be performed, which results in reducing reliability of the touch sensor.

The present invention has been made in view of the aforementioned problems, and an object of the present invention is to provide a display device including an optical sensor, which display device can perform a stable sensing operation under various environments, because the display device is configured to reduce the outside-light-caused noise to the optical sensor and the display device is therefore less susceptible to environment surrounding the display device (outside light intensity etc.).

In order to solve the aforementioned problems, a display device of the present invention includes a display panel including: a photoelectric conversion element, which generates a current having a magnitude corresponding to an intensity of light incident on the photoelectric conversion element; and a light source for irradiating light from behind the photoelectric conversion element to beyond a front surface of the display panel, wherein: the photoelectric conversion element includes an activating layer made of hydrogenated a-Si; the light source has a peak wavelength within a range from 780 nm or more to 830 nm or less; and the display device further comprises a light blocking member for blocking light having a wavelength less than 780 nm, the light blocking member being provided between the front surface of the display panel and the photoelectric conversion element and over the photoelectric conversion element. As a material of the light blocking member, a thin metal film, a member that absorbs light, and the like may be used as long as the member can block light.

Generally, in the case where the activating layer of the photoelectric conversion element is a hydrogenated amorphous silicon (a-Si) layer, a wavelength for obtaining an optimum sensitivity falls within a range from 380 nm to 780 nm.

In the aforementioned configuration, the light source having the peak wavelength within the range from 780 nm or more to 830 nm or less is used, which peak wavelength corresponds to the sensitivity of the photoelectric conversion element which is the activating layer made of hydrogenated a-Si. That is, the sensitivity of the photoelectric conversion element can be maximized, and as a result of this, the optical sensor obtains an excellent sensitivity.

In addition, the light blocking member for blocking the light having a wavelength less than 780 nm is provided over the photoelectric conversion element, to thereby prevent the outside light (visible light) from entering into the photoelectric conversion element.

As described above, the outside light is difficult to enter into the photoelectric conversion element, and hence a function of the optical sensor, i.e., a sensing function can be performed purely between the backlight and the photoelectric conversion element of the device. Unlike a conventional product, there is no need to perform a sensing operation in consideration of the outside light or with use of the outside light, and hence the present invention is less susceptible to environment surrounding the device (outside light intensity etc.), and a stable sensing operation can be performed under various environments.

A display device of the present invention includes a display panel including: a photoelectric conversion element, which generates a current having a magnitude corresponding to an intensity of light incident on the photoelectric conversion element; and a light source for irradiating light from behind the photoelectric conversion element to beyond a front surface of the display panel, wherein: the photoelectric conversion element includes an activating layer made of hydrogenated a-Si; the light source has a peak wavelength within a range from 780 nm or more to 830 nm or less; and the display device further comprises a light blocking member for blocking light having a wavelength less than 780 nm, the light blocking member being provided between the front surface of the display panel and the photoelectric conversion element and over the photoelectric conversion element. With this, the present invention can provide a display device including an optical sensor, which display device can perform a stable sensing operation under various environments, because display device is less susceptible to environment surrounding the device (outside light intensity etc.).

### BRIEF DESCRIPTION OF THE DRAWINGS

FIG. 1 is a schematically sectional view showing a main part of a liquid crystal display device according to an embodiment of the present invention.

FIG. 2 is a block diagram showing a main structure of the liquid crystal display device of FIG. 1.

FIG. 3 is an equivalent circuit diagram for one pixel in the liquid crystal display device of FIG. 2.

FIG. 4 is a graph in which a spectrum of a general light source for illumination, relative sensitivity of an a-Si photoelectric conversion element, and an outside light intensity are related with each other.

FIG. 5 is a graph showing a relationship between a wavelength of a light source and transmission in the case where a general display-use color filter is used as a light blocking member.

FIG. 6 is a plan view of one pixel in the liquid crystal display device of FIG. 2.

FIG. 7 is a sectional view taken along the line A-A′ of the one pixel of FIG. 6.

FIG. 8 is a sectional view taken along the line B-B′ of the one pixel of FIG. 6.

FIG. 9 is a sectional view taken along the line C-C′ of the one pixel of FIG. 6.

FIGS. 10(a) to 10(c) are views illustrating steps in a method for manufacturing the liquid crystal display device of FIG. 1, which steps are performed on an active-matrix-substrate side of the liquid crystal display device.

FIGS. 11(a) to 11(c) are views illustrating steps in a method for manufacturing the liquid crystal display device of FIG. 1, which steps are performed on a counter substrate side of the liquid crystal display device.

### DETAILED DESCRIPTION OF THE INVENTION

An embodiment of the present invention will be described below. Note that this embodiment explains the present invention, referring to a case where a display device of the present invention is applied to a liquid crystal display device including an optical sensor touch panel (hereinafter, referred to as an optical sensor TP system) as an example of an electronic apparatus including a touch panel.

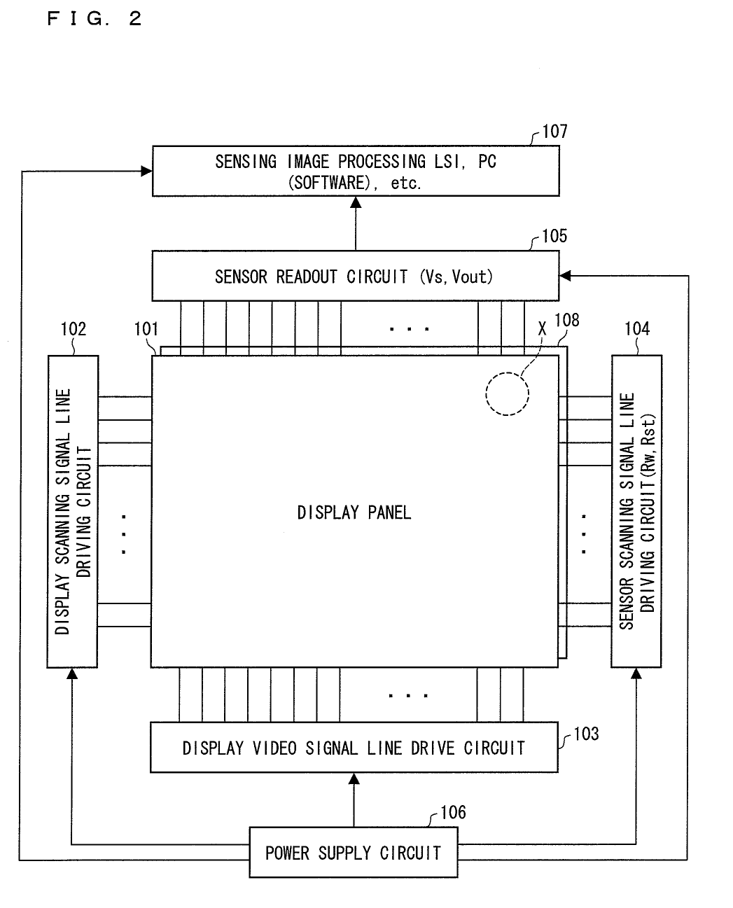

As shown in FIG. 2, the optical sensor TP system according to this embodiment includes: a display panel 101 which includes a photoelectric conversion element (photodiode) as an optical sensor; a display scanning signal line driving circuit 102 and a display video signal line drive circuit 103 which cause the display panel 101 to display an image; a sensor scanning signal line driving circuit 104 and a sensor readout circuit 105 which cause the display panel 101 to function as a touch panel; a sensing image processing LSI 107 (PC (including a software)) which specifies coordinates of a touched portion of the display panel 101 from sensing data read from the sensor readout circuit 105; a light source 108 (hereinafter, referred to as a backlight) which irradiates the display panel 101 with light; and a power supply circuit 106 which supplies power to those circuits.

Note that the liquid crystal display device of FIG. 2 is merely one example, and the present invention is not limited to this configuration. The sensor scanning signal line driving circuit 104 and the sensor readout circuit 105 may be included, as a function, in another circuit (specifically, the display scanning signal line driving circuit 102, the display video signal line drive circuit 103, etc.), or alternatively, may be included, as a function, in the sensing image processing LSI 107.

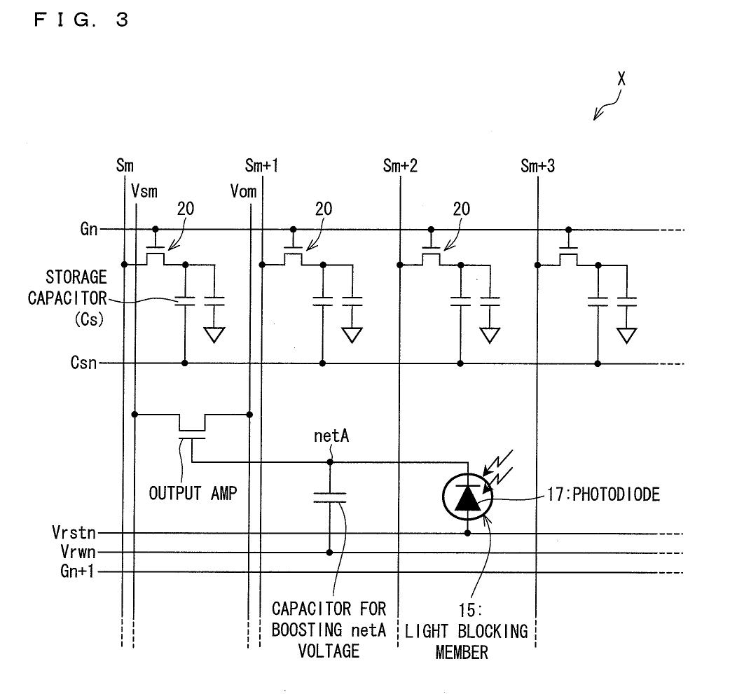

FIG. 3 is an equivalent circuit diagram for one pixel of the display panel 101 of FIG. 2, thereby illustrating the display panel 101 in part under magnification. Note that the display panel 101 is assumed to be an active-matrix liquid crystal display panel in which pixels are arranged in matrix and drive independently. In FIG. 3, the references such as n, n+1, m, and m+1 written at the end of each wiring indicate the nth line, the n+1^{th} line, the m^{th} line, the m+1^{th} line, respectively.

As shown in FIG. 3, one pixel X of the display panel 101 is provided with, as wirings for display, a gate wiring Gn, a source wiring Sm, and a storage capacitor wiring Csn, and is also provided with, as wirings for a detection circuit, a photodiode-resetting wiring Vrstn for resetting a photodiode, a netA voltage-boosting capacitor wiring Vrwn for a capacitor for boosting a netA voltage, a voltage-supply wiring Vsm for supplying a voltage to an output AMP, and a wiring Vom for outputting to the optical sensor.

The gate wiring Gn supplies a scanning signal to a display driving TFT element 20 from the display scanning signal line driving circuit 102. The source wiring Sm is arranged to be orthogonal to the gate wiring Gn, and supplies a video signal to the display driving TFT element 20 from the display video signal line drive circuit 103.

The storage capacitor wiring Csn is arranged to be parallel to the gate wiring Gn, and is connected to a storage capacitor Cs formed in the display driving TFT element 20.

The photodiode-resetting wiring Vrstn is arranged to be parallel to the gate wiring Gn, and is connected to an anode of a photodiode 17 functioning as a photoelectric conversion element. The photodiode-resetting wiring Vrstn supplies a reset signal from the sensor scanning signal line driving circuit 104.

The netA voltage-boosting capacitor wiring Vrwn for the capacitor for boosting the NetA voltage is arranged to be parallel to the gate wiring Gn, and is connected to an electrode arranged on an opposite side of a node (serving as a NetA on a cathode side of the photodiode 17) across a capacitor for boosting a NetA voltage, which is formed in parallel to the node (NetA).

The voltage-supply wiring Vsm for supplying a voltage to an output AMP is arranged to be parallel to the source wiring Sm, and is connected to a source electrode of the output AMP.

The wiring Vom for outputting to the optical sensor outputs an output signal to the sensor readout circuit 105 from the output AMP that outputs the output signal changing in accordance with the amount of light received by the photodiode 17.

Further, the wiring Vom for outputting to the optical sensor is arranged to be parallel to the source wiring Sm, and is connected to a drain electrode of the output AMP.

As shown in FIG. 3, a light blocking member 15 is herein provided over the photodiode 17. The light blocking member 15 may be arranged in proximity to the photodiode 17, or may be also provided on a counter substrate side of the display panel 101. In this embodiment, description will be made of an example where the light blocking member 15 is provided on the counter substrate side.

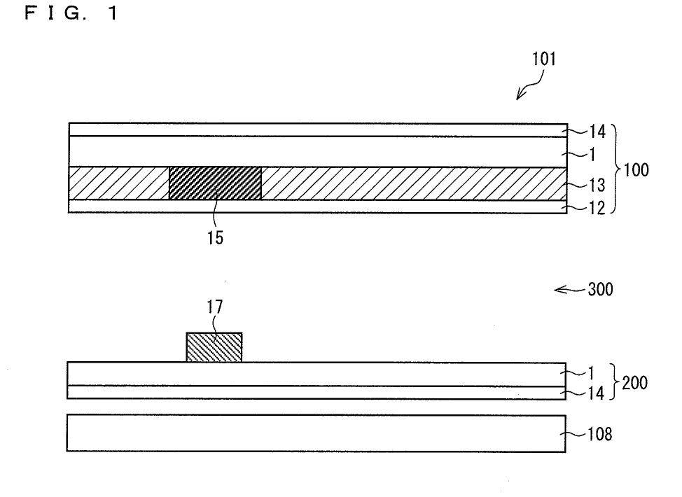

As shown in FIG. 1, the display panel 101 is configured such that a liquid crystal layer 300 is provided between a counter substrate 100 and a TFT array substrate 200. Note that FIG. 1 shows a schematic section of one pixel.

The TFT array substrate 200 is configured such that a polarization film 14 is formed on a surface of an insulating substrate 1 made of a glass plate or the like, and the photodiode 17 and a pixel electrode and wiring (not shown) are formed on the other surface of the insulating substrate 1.

The counter substrate 100 is configured such that a counter electrode 12 is formed on a surface of an insulating substrate 1 made of a glass plate or the like (i.e., similar to the TFT array substrate 200,) via a light blocking film 13, and a polarization film 14 is formed on the other surface of the insulating substrate 1.

When forming the display panel 101, the light blocking film 13 has a shape designed in accordance with locations of a pixel electrode and the photodiode and a pattern of the wirings on the TFT array substrate 200 facing the counter substrate 100 when these substrates are assembled.

The light blocking member 15, which blocks light having a specific frequency component, is formed on a insulating substrate 1 of the counter substrate 100 in the same layer as the light blocking film 13. The light blocking member 15 is arranged over the photodiode 17 on the TFT array substrate 200.

The backlight 108 is placed behind the TFT array substrate 200, i.e., on a side on which the polarization film 14 of the TFT array substrate 200 is formed.

The photodiode 17 herein is a photoelectric conversion element including a photoelectric conversion layer made of a hydrogenated a-Si. It is preferable that a threshold for an increase in sensitivity of a-Si is at a wavelength of 830 nm or less.

Therefore, as the backlight 108, a light source having a peak wavelength within the range from 780 nm or more to 830 nm or less is used.

The light blocking member 15 is arranged over the photodiode 17 as described above, and is made of a member in which an average transmission of light having a wavelength less than that of the visible light (i.e., 780 nm or less) is 1% or less. As an example of such a member, the light blocking member 15 may be formed from a color filter (CF) in which layers of three colors (RGB) are laminated. By forming the light blocking member 15 in this way, the light blocking member 15 can block 99% or more of the light having a wavelength less than the wavelength of the visible light (i.e., 780 nm or less).

The light blocking member 15 is required to block the visible light, i.e., is desired to have a visible light transmission being close to zero as much as possible. That is, the light blocking member 15 preferably blocks 99% or more of the light having a wavelength less than the wavelength of the visible light (i.e., 780 nm or less). Specifically, according to the light blocking member 15, the average transmission of light having a wavelength less than the wavelength of the visible light (i.e., 780 nm or less) is preferably 1% or less. The reason of this will be described below.

It is conceivable that brightness in an indoor environment is about 5000 Lx at a maximum even if the indoor environment has the highest brightness. Thus, it is expected that an intensity of outside light incident on the photodiode 17 be at a maximum, about 50 Lx (=5000 Lx×0.01 (1%)).

Ordinarily, an optical sensor circuit and a display drive circuit constantly receive light within a range from 20 Lx to 30 Lx (stray light) merely from a white backlight for display. Considering this, the optical sensor circuit and the like are designed to have an enough allowance against the above-mentioned light (stray light). Therefore, the outside light (stray light) of 50 Lx is not problematic for the optical sensor circuit and the like.

When the light blocking member 15 has an average transmission exceeding 1% for light having a wavelength less than that of the visible light (i.e., 780 nm or less), an outside light noise (the visible light becomes noise for the photodiode) increases. The outside light noise increases in accordance with increase in the average transmission, for example, in such a way that the outside light noise increases to 100 Lx when the average transmission reaches 2%, and the outside light noise increases to 150 Lx, when the average transmission reaches 3%, and so on. Therefore, an increase in the outside light noise leads to a smaller S/N ratio, that is the ratio between the signal (finger touch information: light that has been reflected on the finger after being emitted from an IR backlight as its light source) and noise (outside light noise: light that has come from outside (outside light as its light source and then transmitted through the light blocking member 15). This decrease in the S/N ratio causes a malfunction (such as positional inaccuracy in the detection or insensitivity in the detection).

Furthermore, the visible light transmission of the light blocking member 15 is preferably 0.4% or less, which is further smaller than 1%. The visible light transmission to 0.4% or less can be realized by laminating the RGB color layers. Laminating three general RGB color layers can reduce the average transmission of the visible light to 0.4%.

In this way, the light blocking member with the visible light transmission of about 0.4% or less can be prepared easily, because the RGB color layers for use in a normal liquid crystal display panel are laminated, and in addition, a conventional process can be employed in laminating the RGB color layers. Furthermore, the preparation of the light blocking member does not require a material especially for the light blocking member, because the light blocking member can be prepared from a general color filter material. Thus, the number of process does not increase. Consequently, it is possible to reduce a cost increase caused by providing the light blocking member.

Hereinafter, the peak wavelength of the light source of the backlight 108 will be described below with reference to FIG. 4 and FIG. 5.

FIG. 4 is a graph in which a spectrum of a general light source for illumination, relative sensitivity of an a-Si photoelectric conversion element, and an outside light intensity are related with each other.

FIG. 5 is a graph showing a relationship between a wavelength of a light source and transmission in the case where a general display-use color filter is used as the light blocking member 15.

The amorphous silicon (a-Si) photoelectric conversion element functioning as the photodiode 17 includes an activating layer made of a-Si. The graph of FIG. 4 shows a measured value as the sensitivity of a-Si. The relative sensitivity of the vertical axis of the graph is calculated from a relationship between a reverse bias current of the photodiode 17 and each of the wavelengths. More specifically, the relative sensitivity is a value of the reverse bias current occurring when light having each wavelength irradiates the photodiode 17 at an equal energy.

First, the relative sensitivity of a-Si will be described.

As shown in the graph of FIG. 4, a wavelength threshold is about 830 nm at which threshold the relative sensitivity of a-Si starts to increase, and a wavelength threshold is about 720 nm at which threshold the relative sensitivity is saturated. That is, the relative sensitivity of a-Si is higher as the wavelength is shorter (i.e., short wavelength). In the aforementioned example, the following relationship can be satisfied: the relative sensitivity having a wavelength of 720 nm the relative sensitivity having a wavelength of 830 nm.

Consequently, in terms of the sensitivity of a-Si, the peak wavelength of the light source is desired to be 830 nm or less.

Next, the outside light intensity will be described. As shown in the graph of FIG. 4, when a wavelength of light of a fluorescent tube for an indoor lighting and a wavelength of a white LED for displaying an image are both more than about 700 nm or more, intensities of incident light of the fluorescent tube and the white LED are sufficiently low (relative intensity is 0.002 or less). Note that the optical intensity is a value obtained by calculating.

Specifically, an absolute intensity of the light incident on the diode is determined by calculating the following expression: intensity of outside light x relative intensity. Further, it is conceivable that brightness in an indoor environment is about 5000 Lx at a maximum even if the indoor environment has the highest brightness. Thus, it is expected that an intensity of outside light be at a maximum, about 50 Lx (=5000 Lx×0.01) as an outside light intensity. Therefore, the 50 Lx is not problematic for the optical sensor circuit and the like.

The reason why the light of 50 Lx is not basically problematic is that the optical sensor circuit and the display drive circuit constantly receive light within the range from 20 Lx to 30 Lx (stray light) merely from the white backlight for display. It is obvious that the optical sensor circuit is designed to have a enough allowance against the above-mentioned light (stray light). so that the accuracy of the optical sensor circuit and the like are not reduced by the light (stray light) and also by the light of 50 Lx incident from the outside (i.e., noise).

Therefore, the light of 50 Lx (i.e., noise) incident from the outside is not problematic.

Note that the average transmission of the visible light of the light blocking member (380 nm to 780 nm) in which the general color layers (RGB) is laminated is 0.4% in an actual measurement.

Next, blocking of the outside light with use of the light blocking member 15 will be described below.

In order to use the photodiode 17 in a wavelength range in which the sensitivity of a-Si increases while the light blocking member 15 blocks the outside light in a wavelength range having high sensitivity of a-Si, the outside light needs to be blocked sufficiently. In the case where a laminate (RGB-CF(color filter)), in which the color layers of RGB-CF are laminated, is employed as the light blocking member 15 for example, the laminate reduces transmission of light having a wavelength of 700 nm or less to 1% or less (in an actual measurement, the average transmission of light having a wavelength within a range from 380 nm to 780 nm is 0.4%). In contrast, in the RGB-CF, transmission of light having a wavelength more than 700 nm rises greatly.

This reduction and rise of the transmission of light can be seen obviously from a graph of FIG. 5. Specifically, it can be found that, in the case of using the light blocking member 15 as a CF layer, three layers (RGB) allows the transmission of light having a wavelength of 700 nm or less to be smaller (1% or less) than each two layers (RG, GB, RB). Note that the light blocking member 15 is not limited to the CF layer of the RGB three layers, any member can be used as long as the member reduces transmission of light having a wavelength of 700 nm or less to 1% or less.

The wavelength range of the visible light is from 380 nm to 780 nm, and hence a wavelength of the light source is preferably 780 nm or more.

Considering the aforementioned points, it can be found that an optimum wavelength of the light source of the backlight 108 is from 780 nm or more to 830 nm or less in order that the sensitivity of the photodiode 17 may be increased and a sensing operation may be performed accurately under various environments without being influenced by the outside light.

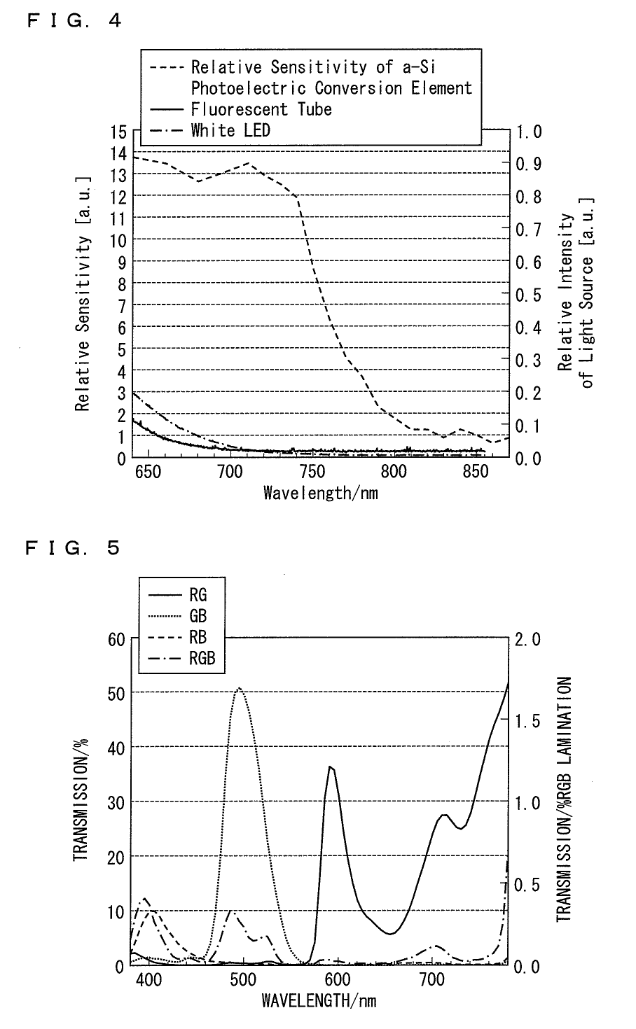

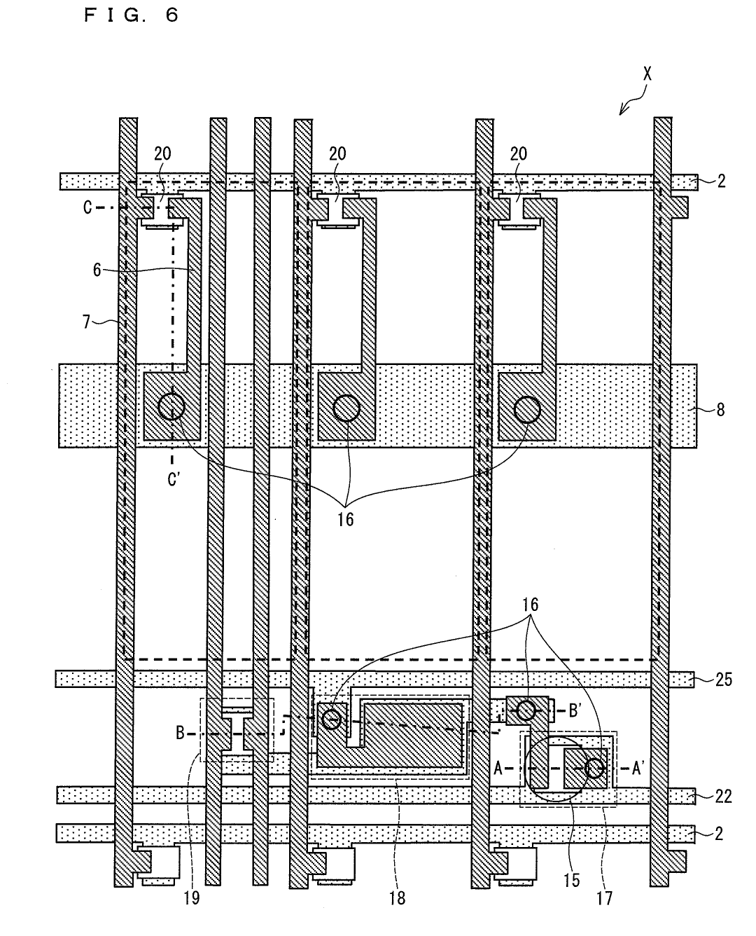

FIG. 6 is a plan view showing a specific wiring structure of the equivalent circuit diagram of the one pixel of FIG. 3.

FIG. 6 shows a wiring and an element structure on a TFT array substrate 200 side of the one pixel, and omits a wiring and an element structure on a counter substrate side thereof.

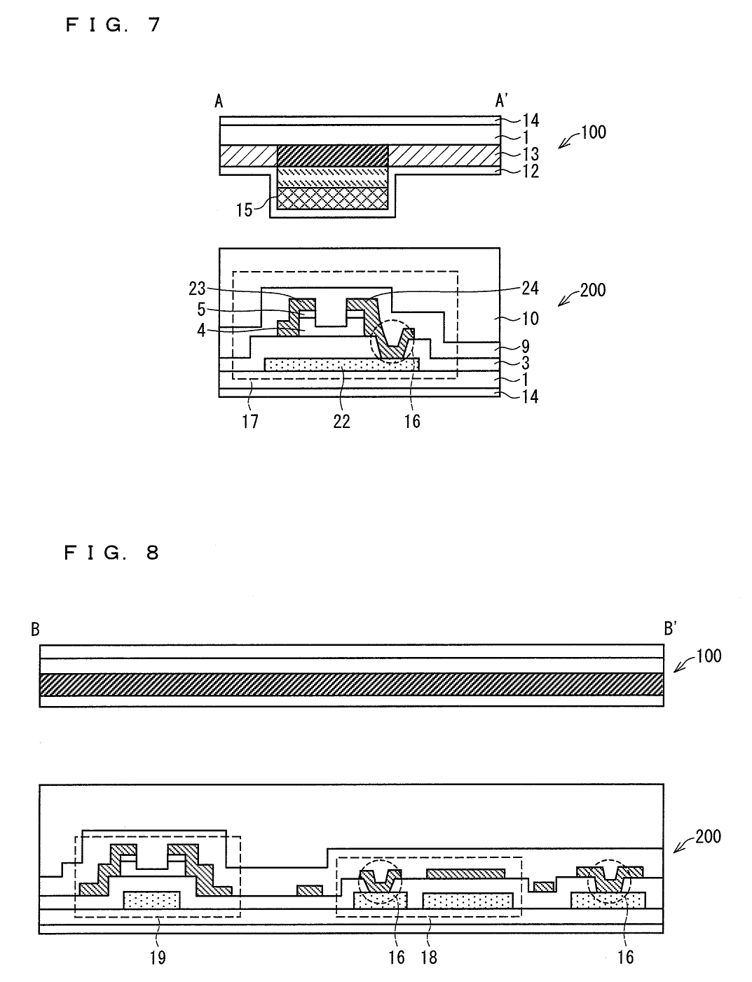

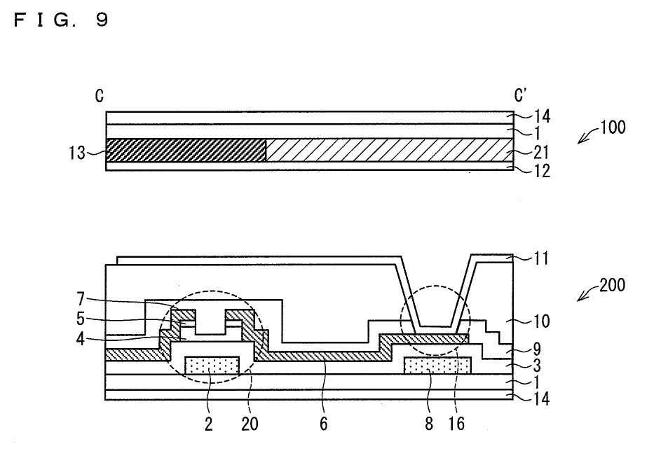

Further, three schematic sectional views in the plan view of FIG. 6 are shown in FIG. 7, FIG. 8, and FIG. 9.

FIG. 7 is a sectional view taken along the line A-A′ of the one pixel of FIG. 6.

FIG. 8 is a sectional view taken along the line B-B′ of the one pixel of FIG. 6.

FIG. 9 is a sectional view taken along the line C-C′ of the one pixel of FIG. 6.

Reference signs in FIG. 6 to FIG. 9 will be described below.

Reference sign 1 denotes the insulating substrate, reference sign 2 denotes a gate substrate and gate wiring, reference sign 3 denotes a gate insulating film, reference sign 4 denotes a semiconductor layer (a-Si), reference sign 5 denotes a contact layer (n+a-Si), reference sign 6 denotes a drain electrode and wiring, reference sign 7 denotes a source electrode and wiring, reference sign 8 denotes a storage capacitor wiring, reference sign 9 denotes a passivation film, reference sign 10 denotes an interlayer insulating film, reference sign 11 denotes a picture element electrode, reference sign 12 denotes the counter electrode, reference sign 13 denotes the light blocking film, reference sign 14 denotes the polarization plate, reference sign 15 denotes the light blocking member, reference sign 16 denotes a contact hole, reference sign 17 denotes the photodiode, reference sign 18 denotes a capacitor for boosting a NetA voltage, reference sign 19 denotes an output AMP, reference sign 20 denotes a TFT for driving a picture element, reference sign 21 denotes a color filter, reference sign 22 denotes a gate electrode and wiring (Vrst wiring) of a photodiode, reference sign 23 denotes a drain electrode and wiring of a photodiode, reference sign 24 denotes a source electrode and wiring of a photodiode, and reference sign 25 denotes a Vrw wiring.

The electrodes and wirings and the elements are configured generally, except that they have the light blocking member 15, and therefore description thereof is herein omitted.

As shown in FIG. 7, the light blocking member 15 is formed as a color filter on the insulating substrate 1 of the counter substrate 100 so as to correspond to the photodiode 17 on the insulating substrate 1 of the TFT array substrate 200. The light blocking member 15 will be described in detail below.

A method for manufacturing the display panel 101 will be described below with reference to the sectional view of FIG. 7.

Note that formation of the photodiode will be described with reference to the sectional view taken along the line A-A′ of FIG. 6 as a representative example, and the sectional views taken along the lines B-B′ and C-C′ are omitted. Herein, forming steps on the TFT array substrate 200 side will be described first, and forming steps on the counter substrate will be described later.

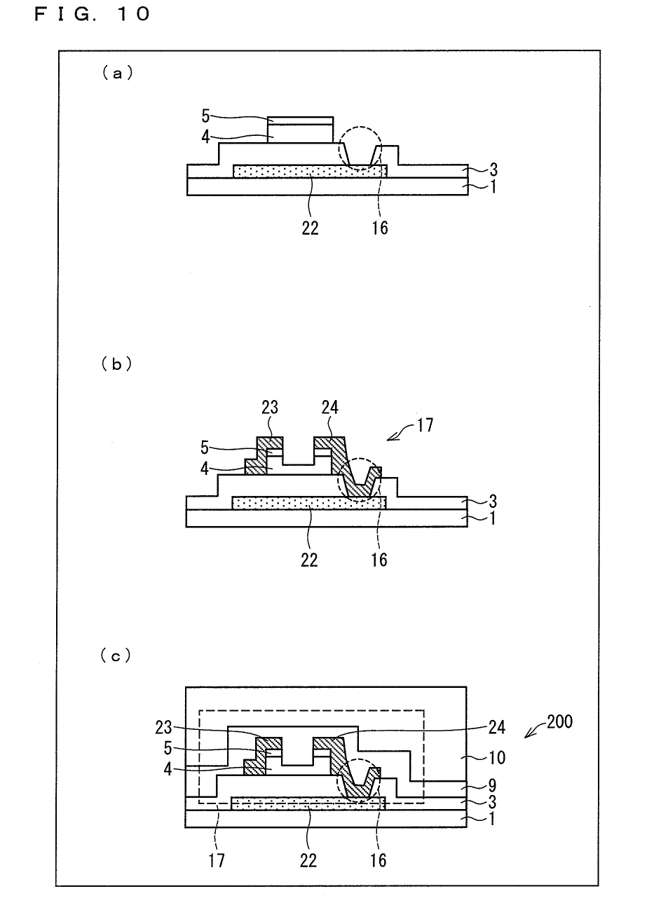

FIGS. 10(a) to 10(c) are views illustrating steps in a method for manufacturing the TFT array substrate 200 side of the display panel 101.

As shown in FIG. 10(a), a metal layer such as Ti/Al/Ti layer is formed on the insulating substrate 1 by the sputtering method so as to have a thickness of about 250 nm, and the gate electrode and wiring (Vrst wiring) 22 of the photodiode is formed by the photolithography method so as to function as the photoelectric conversion element.

Next, the gate insulating film (silicon nitride: SiNx) 3 having a thickness of about 350 nm, the a-Si layer 4 having a thickness of about 150 nm, and the n+-Si layer 5 having a thickness of about 50 nm are formed sequentially by the plasma CVD method, and then are patterned into an island shape by the photolithography method.

Then, in order to form the contact hole 16, terminal pads (not shown) for leading out the gate wiring and source wiring, the gate insulating film 3 is subjected to etching by the photolithography method so as to have predetermined pattern.

Next, as shown in FIG. 10(b), the metal layer such as the Ti/Al/Ti layer is formed sequentially on the insulating substrate 1 by the sputtering method so as to have a thickness of about 250 nm, then the source electrode and wiring 24 of the photodiode and the drain electrode and wiring 23 of the photodiode are formed by the photolithography method. During this formation, the contact hole 16, which has been formed in the forming step of FIG. 10(a), electrically connects the gate electrode and wiring (Vrst wiring) 22 of the photodiode and the source electrode and wiring 24 of the photodiode to each other.

After that, a channel section between the a-Si layer:6 and the n+-Si layer:7 is formed by the dry etching process with use of a gas containing SF6.

In this way, the photodiode 17 can be formed.

Next, as shown in FIG. 10(c), a silicon nitride film is formed as the passivation film 9 by the plasma CVD method so as to have a thickness of about 350 nm, and then a low-dielectric photosensitive resin is formed by the spinning method so as to have a thickness of about 2500 nm to 4500 nm. After that, the contact hole 16 (not shown) for electrically connecting the picture element electrode 11 and the drain electrode and wiring 6 to each other and the terminal pad for leading out the wiring section (not shown) of the gate wiring and source wiring are formed on the photosensitive resin by the photolithography method, to thereby form the interlayer insulating film 10.

Then, the passivation film 9 is subjected to etching by the dry etching process with use of the interlayer insulating film 10 as a mask and a gas containing CF₄/O₂.

Next, a transparent conductive film made of indium thin oxide (ITO) is formed on the interlayer insulating film 10 by the sputtering method so as to have a thickness of about 100 nm, and the picture element electrode 11 is subjected to etching by the photolithography method so as to have a predetermined pattern (not shown).

By employing the aforementioned method, the TFT array substrate 200 of the present invention can be formed.

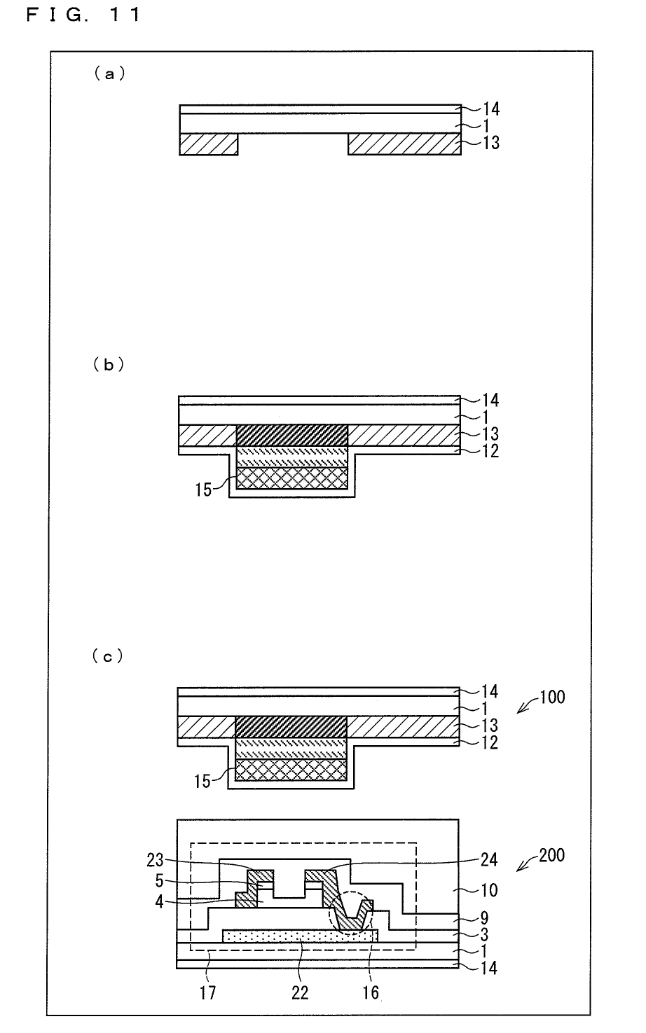

FIGS. 11(a) to 11(c) are views illustrating steps in a method for manufacturing the liquid crystal display device of FIG. 1, which steps are performed on a counter substrate 100 side of the display panel 101.

As shown in FIG. 11(a), after the insulating substrate 1 is baked at substantially 200° C., a resin film having ultraviolet and thermal curing property, and light blocking property is laminated on the insulating substrate 1 while the resin film is raised to about 100° C., then a resin (film thickness: substantially 1600 nm) is transferred.

After that, UV light including light having a wavelength of 365 nm (test wavelength: 365 nm) is irradiated at substantially 70 mJ/cm2 from above the resin (front surface side) with use of a photo mask, and the resin is developed.

Next, by baking the resin at 220° C. for substantially 1 hour, the light blocking film 13 is formed.

Then, as shown in FIG. 11(b), resin films of coloring materials R, G, and B (i.e., the color filter including the three layers of three colors R, G, and B) are formed in substantially the same way as the aforementioned manufacturing method. The resin film having the light blocking effect is not used for this formation. In this way, the color filter is formed to have a desired pattern needed for the light blocking member.

Then, the transparent conductive film made of ITO is formed by the sputtering method, the mask deposition method, or the like, so as to have a thickness of about 100 nm, to thereby form the counter electrode 12 so as to cover the light blocking film 13 and the light blocking member 15.

The TFT array substrate 200 and the counter substrate 100, which have been described above, can form the display panel 101 of FIG. 11(c).

As described above, the display panel 101 having the aforementioned configuration of the liquid crystal display device includes: the photodiode 17, in which a current having a magnitude corresponding to an intensity of light incident from the outside; and the backlight 108 for irradiating light from a back surface side of the photodiode 17 to a front surface side of the display panel 101.

When the photodiode 17 includes the activating layer made of the hydrogenated a-Si and the backlight 108 is a light source having a peak wavelength within the range from 780 nm or more to 830 nm or less, the light blocking member 15 for blocking the light having a wavelength less than 780 nm is provided between the front surface of the display panel 101 and the photodiode 17 and over the photodiode 17.

In the aforementioned configuration, the light source having the peak wavelength within the range from 780 nm or more to 830 nm or less is used as the backlight 108, which peak wavelength corresponds to the sensitivity of the photodiode 17 which is the activating layer made of hydrogenated a-Si. That is, the sensitivity of the photodiode 17 can be maximized, and as a result of this, the optical sensor obtains an excellent sensitivity.

In addition, the light blocking member 15 for blocking the light having a wavelength less than 780 nm is provided over the photodiode 17, to thereby prevent the outside light (visible light) from entering into the photodiode 17.

As described above, the outside light is difficult to enter into the photodiode 17, and hence a function of the optical sensor, i.e., a sensing function can be performed purely between the backlight 108 and the photodiode 17 of the device. Unlike a conventional product, there is no need to perform a sensing operation in consideration of the outside light or with use of the outside light, and hence the present invention is less susceptible to environment surrounding the device (outside light intensity etc.), and a stable sensing operation can be performed under various environments.

The average transmission of the visible light of the light blocking member 15 is preferably 1% or less. Therefore light incident from the outside to the photodiode 17, which is provided over the light blocking member 15, can be blocked.

As described above in this embodiment, the light blocking member 15 for reducing the average transmission to 1% or less is preferably configured to have the color filter including the RGB three layers.

According to the aforementioned configuration, the light blocking member 15 and the display-use color filter provided in the display panel 101 can be formed at the same time, and hence the light blocking member 15 of the present invention can be formed at a lower cost in comparison with the case where a light blocking member 15 is formed with use of a material and step different from a material and step of the display-use color filter.

It is preferable that the aforementioned color filter and the display-use color filter provided in the display panel 101 are identical with each other in terms of the thickness of their layers of respective colors.

The aforementioned configuration enhances the light blocking effect with respect to the visible light, and this enhancement makes the outside light more difficult to enter into the photodiode 17, so that degradation of the accuracy of the sensor can be prevented securely.

The color filter used as the light blocking member 15 is preferably made of a film material.

By forming the light blocking member 15 from a film material, the light blocking effect of the visible light can be more enhanced. In the case where a color filter is made of a liquid material for example, the color filter is formed by applying directly or ejecting the liquid material to a substrate. When the light blocking member is made of the liquid material and by the spinning method (general applying method), a lowest color layer of the color filter has a same film thickness as the display-use color filter. However, when a second color layer of the color filter is formed by applying a liquid crystal resist by the spinning method, the second color layer is laminated on the lowest color layer and is leveled (is planarized), and a thickness of the second color layer becomes consequently smaller than that of the display-use color filter. When a third color layer is laminated, a thickness of the third color layer becomes smaller than that of the second color layer. As a result, the liquid resist is formed into the color filter including the three layers (RGB) having a low light blocking effect. Meanwhile, in the case where the color filter is formed by ejecting the liquid material, if the liquid material cannot be applied or ejected well, the liquid material does not form a uniform film. Thus, excess outside light may enter into the display panel. In contrast, use of the color filter made of a film material means that a uniform film is originally formed, and the color filter consequently prevents the excess outside light from entering into the display panel.

As described above, the average transmission of the visible light of the light blocking member 15 is preferably 1% or less, and more preferably 0.4% or less.

According the aforementioned configuration, it becomes possible to block the light incident from the outside to the photodiode 17 serving as the photoelectric conversion element, which is provided over the light blocking member 15.

As described above, the light blocking member 15 for reducing the transmission average of the visible light to 1% or less is preferably configured to have the color filter of the RGB three layers.

According to the aforementioned configuration, the light blocking member 15 and the display-use color filter provided in the display panel 101 can be formed at the same time, and hence the light blocking member 15 of the present invention can be formed at a lower cost in comparison with the case where a light blocking member 15 is formed with use of a material and step different from a material and step of the display-use color filter.

It is preferable that the aforementioned color filter and the display-use color filter provided in the display panel 101 are identical with each other in terms of the thickness of their layers of respective colors.

The aforementioned configuration enhances the light blocking effect with respect to the visible light, and this enhancement makes the outside light more difficult to enter into the photodiode 17, so that degradation of the accuracy of the sensor can be prevented securely.

Generally, a color filter is made of the liquid resist. In this case, a lowest color layer of the color filter has a same film thickness as the display-use color filter. However, when a second color layer of the color filter is formed by applying the liquid resist by the spinning method, the second color layer is laminated on the lowest color layer and is leveled (is planarized), so that a thickness of the second color layer is smaller than that of the display-use color filter. When a third color layer is laminated, a thickness of the third color layer is smaller than that of the second color layer. As a result, the liquid resist is formed into the color filter including the three layers (RGB) having a low light blocking effect. For example, thickness of the third color layer, the second color layer, the lowest color layer is 20 nm/50 nm/150 nm, respectively.

In order to enhance the light blocking effect with respect to the visible light, it is preferable that the aforementioned color filter and the display-use color filter provided in the display panel are identical with each other in terms of the thickness of their layers of respective colors.

The color filter is preferably made of a film material.

The aforementioned configuration can prevent reduction in film thickness caused by the leveling that occurs when, for example, applying the liquid light blocking member 15, and in addition the light blocking member having the high light blocking effect can be formed easily.

The display panel 101 is preferably a liquid crystal display panel, as described above.

The present invention can be preferably used for a touch panel of a portable terminal, such as a cellular phone.

The display device having the aforementioned configuration is applicable to various electronic apparatuses needed to provide a touch panel.

An example of the electronic apparatuses encompasses, in addition to portable terminal such as a cellular phone, an electronic apparatus provided with a touch panel.

Specifically, the electronic apparatuses encompass operation monitors, which are provided in a cellular phone, a PC monitor, various commercial electrical equipment (for example, ATM), and the like.

The present invention is not limited to the description of the embodiments above, and may be modified in numerous ways by a skilled person as long as such modification falls within the scope of the claims. An embodiment based on a proper combination of technical means disclosed in different embodiments is encompassed in the technical scope of the present invention.

The present invention is preferably applicable to an electronic apparatus providing a touch panel.

### REFERENCE SIGNS LIST

1 insulating substrate
3 gate insulating film
6 drain electrode and wiring
9 passivation film
10 interlayer insulating film
11 picture element electrode
12 counter electrode
13 light blocking film
14 polarization film
15 light blocking member
16 contact hole
17 photodiode
20 display driving TFT element
23 drain electrode and wiring
24 source electrode and wiring
100 counter substrate
101 display panel
102 display scanning signal line driving circuit
103 display video signal line drive circuit
104 sensor scanning signal line driving circuit
105 sensor readout circuit
106 power supply circuit
107 sensing image processing LSI
108 backlight
200 TFT array substrate
300 liquid crystal layer

1. A display device, comprising:
a display panel including:
a photoelectric conversion element, which generates a current having a magnitude corresponding to an intensity of light incident on the photoelectric conversion element; and
a light source for irradiating light from behind the photoelectric conversion element to beyond a front surface of the display panel,
wherein:
the photoelectric conversion element includes an activating layer made of hydrogenated a-Si;
the light source has a peak wavelength within a range from 780 nm or more to 830 nm or less; and
the display device further comprising a light blocking member for blocking light having a wavelength less than 780 nm, the light blocking member being provided between the front surface of the display panel and the photoelectric conversion element and over the photoelectric conversion element.

2. The display device as set forth in claim 1, wherein an average transmission of the light blocking member is 1% or less for visible light.

3. The display device as set forth in claim 2, wherein the average transmission of the light blocking member is 0.4% or less for visible light.

4. The display device as set forth in claim 2, wherein the light blocking member is made of a color filter including RGB three layers.

5. The display device as set forth in claim 4, wherein the color filter and a display-use color filter are identical with each other in terms of thickness of layers of respective colors, the display-use color filter being provided in the display panel.

6. The display device as set forth in claim 4, wherein the color filter is made of a film material.

7. The display device as set forth in claim 1, wherein the display panel is a liquid crystal display panel.

8. An electronic apparatus, comprising the display device as set forth in claim 1.
